(19) United States
(12) Patent Application Publication
(10) Pub. No.: US 2017/0062393 A1
(43) Pub. Date: Mar. 2, 2017

(54) DISPLAY DEVICE AND METHOD OF MANUFACTURING THE SAME

(71) Applicant: Samsung Display Co., Ltd., Yongin-Si (KR)

(72) Inventor: Mugyeom Kim, Yongin-si (KR)

(21) Appl. No.: 15/193,323

(22) Filed: Jun. 27, 2016

(30) Foreign Application Priority Data
Aug. 31, 2015 (KR) 10-2015-0123195

(51) Int. Cl. H01L 25/075; H01L 33/00; H01L 33/32; H01L 33/62; H01L 33/06

(52) U.S. Cl. CPC H01L 25/0753; H01L 33/62; H01L 33/06; H01L 33/32; H01L 33/0079; H01L 2933/0066

(57) ABSTRACT

A method of manufacturing a display device includes: immersing a mask including openings, in a solution; seating light-emitting diode chips respectively in the openings of the mask; arranging a first flexible substrate including first wirings thereon, below the mask, and aligning the first wirings to respectively correspond to the openings of the mask; removing from the solution, the first flexible substrate with the first wirings corresponding to the openings of the mask together with the mask with the light-emitting diode chips seated in the openings thereof; bonding the light-emitting diode chips and the first wirings to each other; providing a second flexible substrate including second wirings thereon, and aligning the second wirings to respectively correspond to the light-emitting diode chips; and bonding the light-emitting diode chips and the second wirings to each other, to form the display device.

This application claims priority to Korean Patent Application No. 10-2015-0123195, filed on Aug. 31, 2015, and all the benefits accruing therefrom under 35 U.S.C. §119, the content of which in its entirety is herein.

### BACKGROUND

1. Field

One or more exemplary embodiments relate to a method of manufacturing a display device including a light-emitting diode (“LED”) and a display device manufactured by using the manufacturing method.

2. Description of the Related Art

A light-emitting diode (“LED”) is a semiconductor device in which a hole and an electron are injected when a forward voltage is applied to a PN-junction diode, and energy generated by recombination of the hole and the electron is converted to light energy.

An inorganic LED that emits light by using an inorganic compound is widely used for a backlight of a liquid crystal display television (“LCD TV”), an electric light, an electronic display board, etc., and an organic LED that emits light by using an organic compound is used for a miniature electronic apparatus such as a mobile phone, and a large-scale TV, etc.

### SUMMARY

An inorganic light-emitting diode (“LED”) is relatively low-priced, brighter and has a relatively long life compared with an organic LED, but unlike an organic LED, cannot be directly formed on a flexible substrate by using a thin film process.

One or more exemplary embodiments include a method of manufacturing a flexible and/or stretchable display device by transferring an inorganic LED to a flexible substrate.

According to one or more exemplary embodiments, a method of manufacturing a display device includes: immersing a mask including an opening defined therein in plural, in a solution; seating a light-emitting diode chip provided in plural respectively in the openings of the mask in the solution; in the solution, arranging a first flexible substrate including a first wiring in plural thereon, below the mask, and aligning the first wirings on the first flexible substrate to respectively correspond to the openings of the mask; removing from the solution, the first flexible substrate with the first wirings corresponding to the openings of the mask together with the mask with the light-emitting diode chips seated in the openings thereof; bonding the light-emitting diode chips and the first wirings to each other; and providing a second flexible substrate including a second wiring in plural thereon, aligning the second wirings on the second flexible substrate to respectively correspond to the light-emitting diode chips; and bonding the light-emitting diode chips and the second wirings to each other, to form the display device.

The seating the light-emitting diode may further include: seating a single one light-emitting diode chip in each of the openings of the mask.

The second wirings may extend lengthwise in a direction crossing a direction in which the first wirings lengthwise extend.

The openings may respectively correspond to locations where the first wirings cross the second wirings.

The method may further include: removing the mask from the light-emitting diode chips seated in the openings thereof, before the bonding the light-emitting diode chips and the first wirings to each other.

The method may further include for each light-emitting diode chip seated in the mask: disposing a first electrode pad on a first end of the light-emitting diode chip before the seating the light-emitting diode chip.

The first electrode pad may include a material having a density greater than that of the light-emitting diode chip.

The bonding the light-emitting diode chips and the first wirings to each other may include bonding the first electrode pad to the first wiring by using pressurization and/or Joule heat.

The solution may include fluorine.

The mask may include a magnetic material, and the light-emitting diode chip may be coated with the magnetic material.

The light-emitting diode chips may each include a semiconductor compound. The method may further include disposing the light-emitting diode chips including the semiconductor compound on a base substrate, processing the light-emitting diode chips disposed on the base substrate to be separable from the base substrate, transferring the separable light-emitting diode chips to a carrier substrate, and removing the base substrate from the separable light-emitting diode chips to dispose the light-emitting diode chips on the carrier substrate.

A minimum size of the opening of the mask may be greater than a maximum size of the light-emitting diode chip.

The seating the light-emitting diode chip in the opening of the mask in the solution may include moving the light-emitting diode chip up and down in the solution by using a laser.

The seating the light-emitting diode chip in the opening of the mask in the solution may include moving the light-emitting diode chip up and down in the solution by using an ultrasonic wave.

Both a width of the first wiring taken perpendicular to a length thereof and a width of the second wiring taken perpendicular to a length thereof, may be less than a width of the light-emitting diode chip taken perpendicular to a length thereof.

According to one or more exemplary embodiments, a display device manufactured by using the above-described manufacturing method is provided.

According to an exemplary embodiment, since a mask including an opening corresponding to a wiring having a passive matrix (“PM”) structure is used, transferring and aligning a light-emitting diode with the wiring may be performed relatively simply.

Also, since a display device having the PM structure is manufactured, power consumption of the display device may be reduced.

Also, a flexible display device deformable in up/down directions and left/right directions may be manufactured by using a relatively simple process.

### BRIEF DESCRIPTION OF THE DRAWINGS

These and/or other features will become apparent and more readily appreciated from the following description of the exemplary embodiments, taken in conjunction with the accompanying drawings in which:

FIG. 1 is a flowchart illustrating an exemplary embodiment of a manufacturing method of a display device according to the invention;

FIGS. 2A and 2B are a top plan view and a cross-sectional view illustrating an exemplary embodiment of a plurality of light-emitting diodes (“LEDs”) on a base substrate according to the invention;

FIG. 3 is a cross-sectional view illustrating an exemplary embodiment of an attached state of a carrier substrate and the plurality of LEDs of FIGS. 2A and 2B;

FIG. 4 is a cross-sectional view illustrating an exemplary embodiment of an unattached state of the carrier substrate on which the plurality of LEDs of FIG. 3 are disposed;

FIG. 5 is a cross-sectional view illustrating an exemplary embodiment of a process in which a mask is immersed in a solution, and a plurality of LED chips are dropped above the mask;

FIG. 6 is a top plan view illustrating an exemplary embodiment of the mask in FIG. 5;

FIG. 7 is a cross-sectional view illustrating an exemplary embodiment of a process in which an LED chip is disposed in each opening of the mask;

FIG. 8 is a cross-sectional view illustrating an exemplary embodiment of a state of the LED chip disposed in the each opening of the mask;

FIG. 9 is a cross-sectional view illustrating an exemplary embodiment of a process in which a first flexible substrate including a first wiring is disposed below the mask in which the LED chips are disposed;

FIG. 10 is a cross-sectional view illustrating an exemplary embodiment of a state in which the LED chip is disposed on the first flexible substrate;

FIG. 11 is a cross-sectional view illustrating an exemplary embodiment of a process in which the LED chip is connected with the first wiring;

FIG. 12 is a cross-sectional view illustrating an exemplary embodiment of an assembled state of the display device for which a plurality of LED chips are disposed on a first flexible substrate, and a second flexible substrate is aligned with the plurality of LED chips;

FIGS. 13A and 13B are top plan views of the display device in FIG. 12; and

FIG. 14 is a perspective view of the display device in FIG. 12.

### DETAILED DESCRIPTION

Reference will now be made in detail to exemplary embodiments, examples of which are illustrated in the accompanying drawings, where like reference numerals refer to like elements throughout. In this regard, the exemplary embodiments may have different forms and should not be construed as being limited to the descriptions set forth herein. Accordingly, the exemplary embodiments are merely described below, by referring to the figures, to explain features of the invention.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms. Expressions such as “at least one of” when preceding a list of elements, modify the entire list of elements and do not modify the individual elements of the list. As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

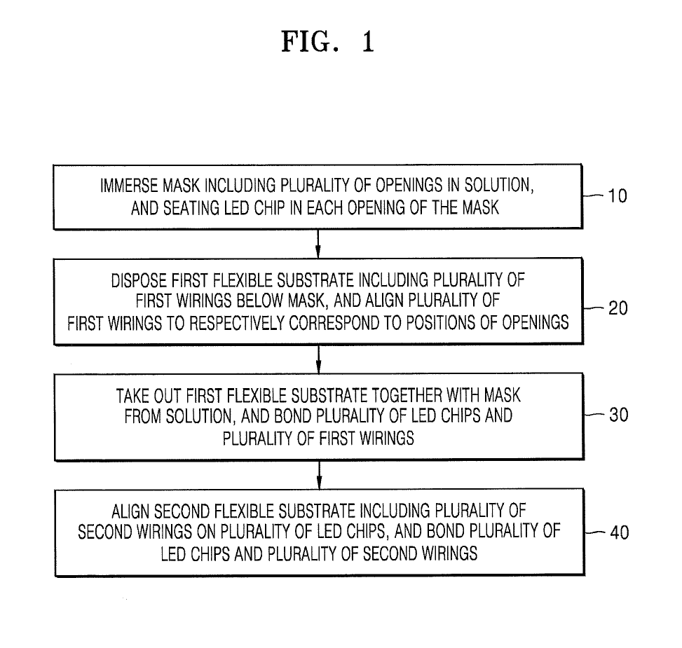

FIG. 1 is a flowchart illustrating an exemplary embodiment of a manufacturing method for a display device according to the invention.

Referring to FIG. 1, an exemplary embodiment of a method of manufacturing a display device according to the invention includes an operation 10 of immersing a mask including a plurality openings in a solution, and seating a light-emitting diode (“LED”) chip in each of the openings of the mask, an operation 20 of disposing a first flexible substrate including a plurality of first wirings below the mask, and aligning the plurality of first wirings to respectively correspond to positions of the openings, an operation 30 of taking out the first flexible substrate together with the mask from the solution, and bonding the plurality of LED chips and the plurality of first wirings to each other, and an operation 40 of aligning a second flexible substrate including a plurality of second wirings on the plurality of LED chips, and bonding the plurality of LED chips and the plurality of second wirings.

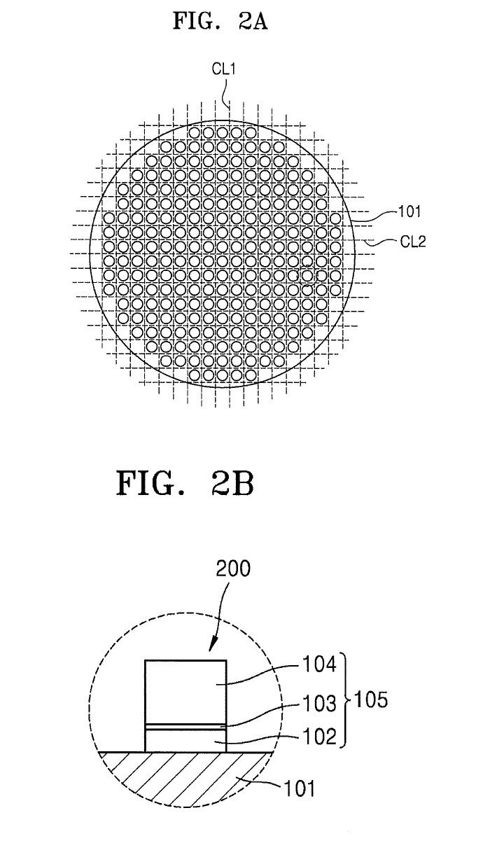

The manufacturing method of FIG. 1 is described below with reference to FIGS. 2 to 14.

FIGS. 2A and 2B are respectively a top plan view and a cross-sectional view illustrating a light-emitting diode (“LED”) 105 is provided in plural on a base substrate 101

The base substrate 101 may include a conductive substrate or an insulating substrate. In an exemplary embodiment, for example, the base substrate 101 may include at least one of Al₂O₃, SiC, Si, GaAs, GaN, ZnO, Si, GaP, InP, Ge, and Ga₂O₃.

The LED 105 may include a first semiconductor layer 102, a second semiconductor layer 104, and an active layer 103 disposed between the first semiconductor layer 102 and the second semiconductor layer 104. The first semiconductor layer 102, the active layer 103 and the second semiconductor layer 104 may be formed by using methods such as metal organic chemical vapor deposition (“MOCVD”), chemical vapor deposition (“CVD”), plasma-enhanced chemical vapor deposition (“PECVD”), molecular beam epitaxy (“MBE”) and hydride vapor phase epitaxy (“HVPE”).

The first semiconductor layer 102 may be implemented as, for example, a p-type semiconductor layer. The p-type semiconductor layer may include a semiconductor material having a composition equation of InₓAl_{y}Ga_{1-x-y}N (0≦x≦1, 0≦y≦1, 0≦x+y≦1), and may include, for example, GaN, AlN, AlGaN, InGaN, InN, InAlGaN, AlInN, etc. The first semiconductor layer 102 may be doped with p-type dopants such as Mg, Zn, Ca, Sr and Ba.

The second semiconductor layer 104 may include, for example, an n-type semiconductor layer. An n-type semiconductor layer may include a semiconductor material having a composition equation of InₓAl_{y}Ga_{1-x-y}N (0≦x≦1, 0≦y≦1, 0≦x+y≦1), and may include, for example, GaN, AlN, AlGaN, InGaN, InN, InAlGaN, AlInN, etc. The second semiconductor layer 104 may be doped with n-type dopants such as Si, Ge and Sn.

However, the invention is not limited thereto. In an alternative exemplary embodiment, the first semiconductor layer 102 may include the n-type semiconductor layer and the second semiconductor layer 104 may include the p-type semiconductor layer.

The active layer 103 is a region in which an electron and a hole recombine. When the electron and the hole recombine, they may make a transition to a lower energy level and emit light having a corresponding wavelength. The active layer 103 may include a semiconductor material having a composition equation of InₓAl_{y}Ga_{1-x-y}N (0≦x≦1, 0≦y≦1, 0≦x+y≦1), and may include a single quantum well structure or a multi-quantum well (“MQW”) structure. Also, the active layer 103 may include a quantum wire structure or a quantum dot structure.

The plurality of LEDs 105 disposed on the base substrate 101 is processed such that the plurality of LEDs 105 are separable from the base substrate 101. In an exemplary embodiment, a cut or score is disposed along cutting lines CL1 and CL2 by using a laser, etc., such that the plurality of LEDs 105 are allowed to be in a separable state from the base substrate 101.

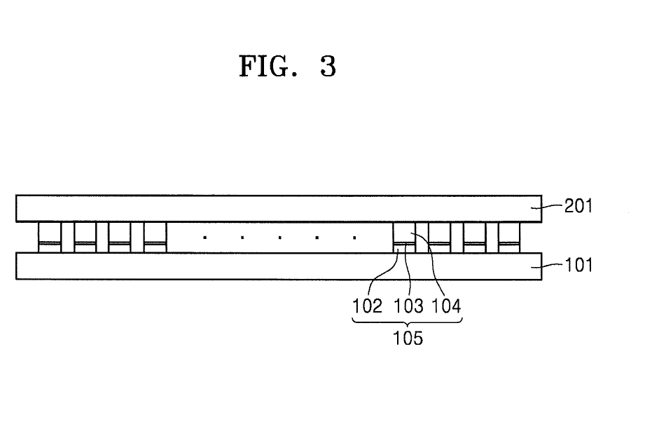

FIG. 3 is a cross-sectional view illustrating an exemplary embodiment of an attached state of a carrier substrate and the plurality of LEDs 105 disposed on the base substrate 101.

With the plurality of LEDs 105 in a separable state from the base substrate 101, but while still disposed on the base substrate 101, the carrier substrate 201 is attached on the second semiconductor layers 104 of the LEDs 105. The position of the LEDs 105 is temporarily fixed on the carrier substrate 201 such as by using an adhesive layer (not shown), etc.

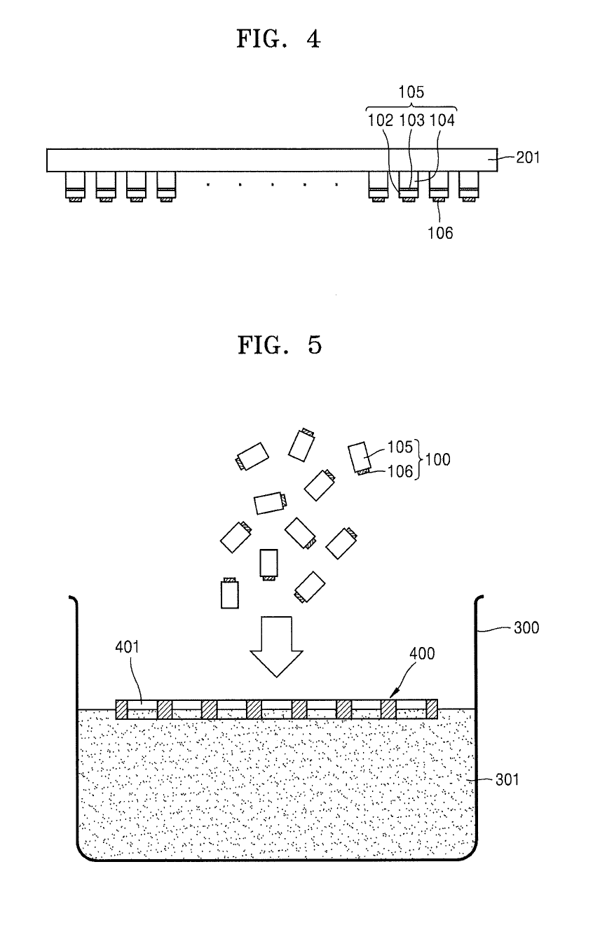

FIG. 4 is a cross-sectional view illustrating an exemplary embodiment of an unattached state of the carrier substrate on which the LEDs 150 of FIG. 3 are disposed. In FIG. 4, the base substrate 101 of FIG. 3 is separated from the LEDs 105 and a first electrode pad 106 is provided in plural respectively on the LEDs 105.

The base substrate 101 is separated from the LEDs 105 such as by using a laser lift-off process, and the separated LEDs 105 are attached to the carrier substrate 201. For the LEDs 105 attached to the carrier substrate 201, the first electrode pad 106 is disposed on a distal end of the LEDs 105 at the first semiconductor layers 102 thereof from which the base substrate 101 has been removed. The LED 105 with the first electrode pad 106 thereon forms a LED chip 100. The electrode pad 106 of the LED chip 100 may define a relatively high density portion of the LED chip 100, such as due to a material from which the first electrode pad 106 is formed.

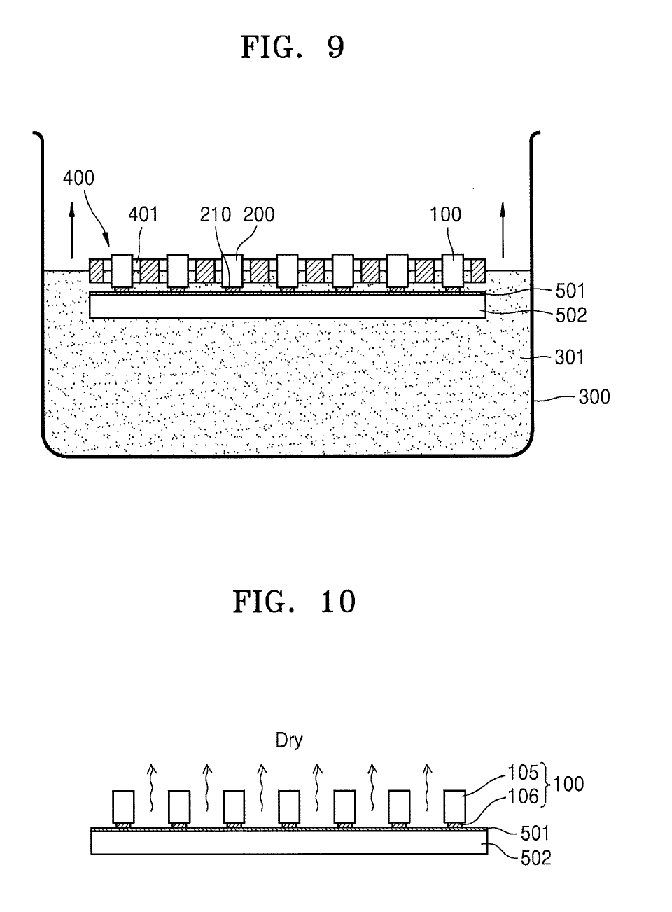

The first electrode pad 106 may include one or more layers, and may include various conductive materials such as metal, a conductive oxide and conductive polymers. The first electrode pad 106 will be electrically connected to a first wiring 501 (see FIG. 9) on a first flexible substrate 502 (see FIG. 9) which will be described later.

FIGS. 2A, 2B, 3 and 4 illustrate a plurality of LEDs 105 have a straight line type lateral wall in a cross-section and a circular shape in the top plan view. That is, the LEDs 105 may have a cylindrical shape to define a cylindrical shape of the LED chip 100, but the invention is not limited thereto.

Though FIGS. 2A, 2B, 3 and 4 illustrate a plurality of LEDs 105 have a straight line type lateral wall in a cross-section, the LED 105 may have a lateral wall which is tapered in the cross-section. Referring to FIG. 2B for example, the wall of the LED 105 may taper in a direction from up to down or from down to up.

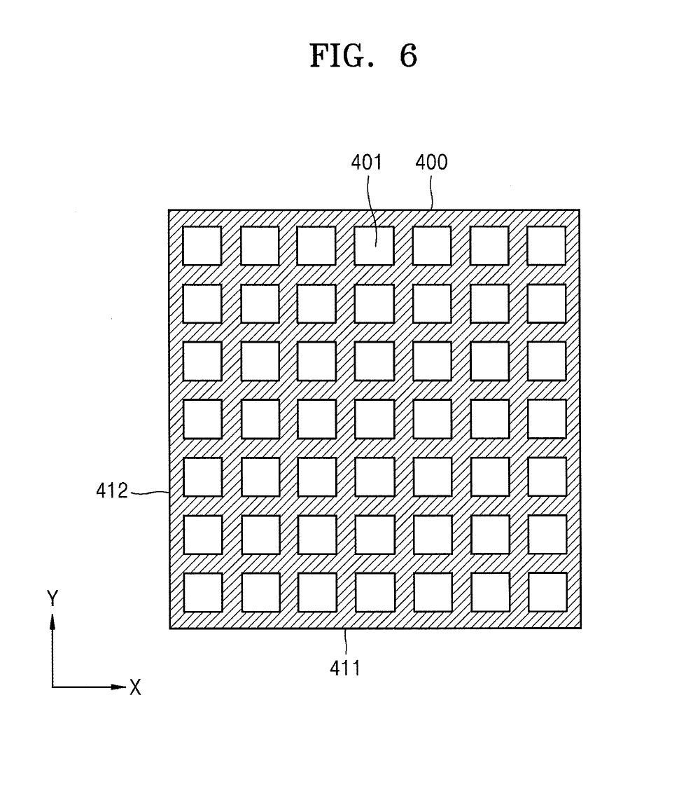

FIG. 5 is a cross-sectional view illustrating an exemplary embodiment of a process in which a mask 400 including a plurality of openings 401 is immersed in a solution, and a plurality of LED chips 200 are dropped above the mask 400. FIG. 6 is a top plan view illustrating an exemplary embodiment of the mask 400 in FIG. 5.

Referring to FIGS. 5 and 6, the plurality of openings 401 may be formed in the mask 400 at positions where a first direction X parallel to a first side edge 411 of the mask 400 crosses a second direction Y parallel to a second side edge 412 of the mask 400 perpendicular to the first side edge 411 thereof.

Since the mask 400 includes and defines the plurality of openings 401 therein, even when the mask 400 is immersed in a container 300 containing a solution 301, the mask 400 does not sink to the bottom of the container 300 but instead floats in the neighborhood of the uppermost surface of the solution 301. To support the mask 400 floating at the uppermost surface of the solution 301, a material such as fluorine that reduces surface tension may be further added to the solution 301.

The carrier substrate 201 is separated from the second semiconductor layers 104 of the LEDs 105 to separate the plurality of LED chips 100 from the carrier substrate 201. The separated plurality of LED chips 100 including the LEDs 105 having the first electrode pads 106 respectively thereon are dropped toward the container 300 from a position above the mask 400 in the container 300.

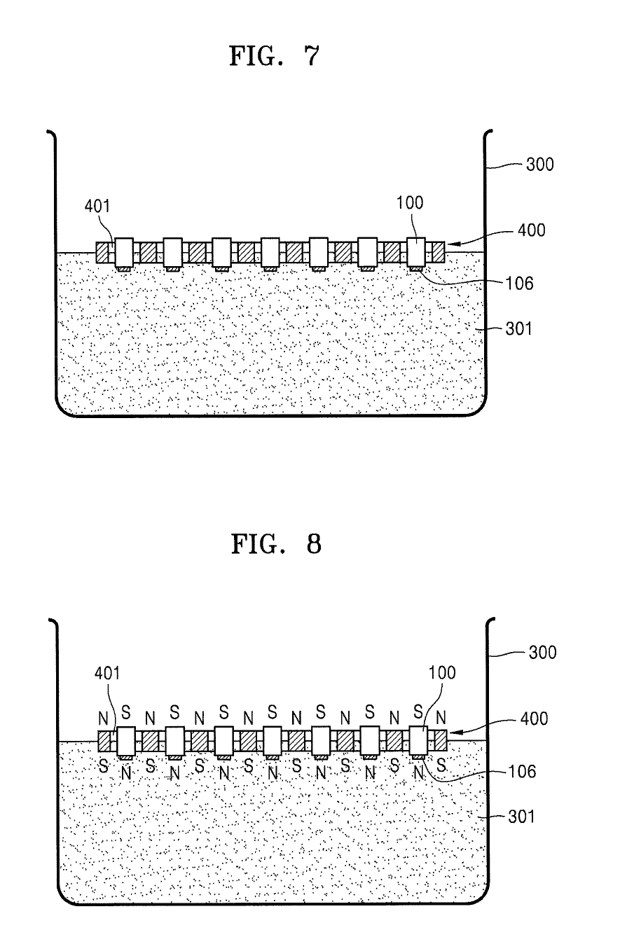

FIG. 7 is a cross-sectional view illustrating an exemplary embodiment of a process in which a separated LED chip 100 is disposed in each opening 401 of the mask 400.

The separated LED chip 100 dropped from a position above the mask 400 settles in an opening 401 defined in the mask 400. For settling the dropped LED chips 100 into the openings 401 of the mask 400, the LED chips 100 may be uniformly disposed or spread over the entire mask 400 such as by using a brush (not shown), etc.

The LED chip 100 is positioned at the upper surface of the solution 301 so that a portion of the LED chip 100 at which the first electrode pad 106 having the relatively high density may face downward. In an exemplary embodiment, for example, since the density of silicon forming a semiconductor LED is about 2.33 grams per cubic centimeter (g/cm³), where the first electrode pad 106 includes aluminum having a density of about 2.70 g/cm³ or silver having density of about 10.49 g/cm³, an LED chip 100 may be disposed in each opening 401 with the portion including the first electrode pad 106 reversed in position to be disposed in a downward direction. If unreversed LED chips 100 remain disposed over the mask 400, positions thereof may be reversed such as by using an ultrasonic wave or a laser. A degree to which the positions of the unreversed LED chips 100 are reversed may be determined such as by measuring reflectivity.

A size of the opening 401 is larger than that of the LED chip 100 so that the LED chip 100 may rotate up and down while disposed within the opening 401 of the mask 400 in the solution 301. In an exemplary embodiment, for example, a minimum dimension of the opening 401 in the top plan view may be larger than a maximum of every dimension of the LED chip 100, to allow the LED chip 100 to rotate while disposed within the opening 401. Only one LED chip 100 may be disposed in a single opening of the mask 401.

FIG. 8 is a cross-sectional view illustrating an exemplary embodoiment of a state of the LED chip 100 disposed in each opening 401 of the mask 400.

FIG. 8 illustrates an exemplary embodiment in which the mask 400 includes a magnetic material (indicated by “S” and “N”), and the LED chip 100 is coated with a magnetic material (indicated by “N” and “S”) to have magnetism. The LED chip 100 rotates within the opening 401 due to a magnetic field within the fluid form solution and as a result of the magnetic field is disposed so that a portion thereof including the first electrode pad 106 may face downward.

FIG. 9 is a cross-sectional view illustrating an exemplary embodiment of a process in which a first flexible substrate 502 including a first wiring 501 thereon is disposed below the mask 400 for which the LED chip 100 is disposed in each opening 401 thereof. The first wiring 501 may be provided in plural to form a collective first wiring member.

The plurality of first wirings 501 are disposed to respectively correspond to the positions of the plurality of openings 401 defined in the mask 400. Since the LED chip 100 is located in each opening 401 of the mask, the first wiring 501 is aligned to pass below the lower portion of the LED chip 100. A single first wiring 501 may pass below a lower portion of more than one LED chip 100 and the opening 401 in which the LED chip 100 is seated.

The first flexible substrate 502 may include a plastic material. In an exemplary embodiment, for example, the first flexible substrate 502 may include polyether sulphone (“PES”), polyacrylate (“PAR”), polyether imide (“PEI”), polyethylene naphthalate (“PEN”), polyethylene terepthalate (“PET”), polyphenylene sulfide (“PPS”), polyallylate, polyimide, polycarbonate (“PC”), cellulose triacetate (“TAC”), and cellulose acetate propionate (“CAP”).

The first wiring 501 may include a relatively low resistance metallic material. In an exemplary embodiment, for example, the first wiring 501 may include a single layer structure or a multi layer structure including at least one of Al, Pt, Pd, Ag, Mg, Au, Ni, Nd, Ir, Cr, Li, Ca, Mo, Ti, W and Cu.

The first wiring 501 is lengthwise extended to define an extension direction thereof, and a width of the first wiring 501 is defined perpendicular to the extension direction thereof. Similarly, the LED chip 100 is lengthwise extended to define an extension direction thereof, and a width of the LED chip 100 is defined perpendicular to the extension direction thereof. The width of the LED chip 100 may be a diameter of the LED chip 100 when the LED chip 100 has a cylindrical shape. The width of the first wiring 501 is smaller than that of the LED chip 100.

FIG. 10 is a cross-sectional view illustrating an exemplary embodiment of a state in which the LED chip 100 is disposed on the first flexible substrate 502.

Referring to FIG. 10, the flexible substrate 502 together with the mask 400 having the LED chips 100 disposed therein is removed from the solution 301. In an exemplary embodiment, while out of the solution 301, the removed mask 400 is separated from the LED chips 100 disposed therein such that the LED chips 100 remain on the first flexible substrate 502 having the first wiring 501. With the LED chips 100 remaining on the first flexible substrate 502 having the first wiring 501, residual solution 301 remaining on the flexible substrate 502 is dried (indicated by “Dry”). The LED chips 100 remaining on the first flexible substrate 502 having the first wiring 501 may be in an unconnected state relative to the first wiring 501.

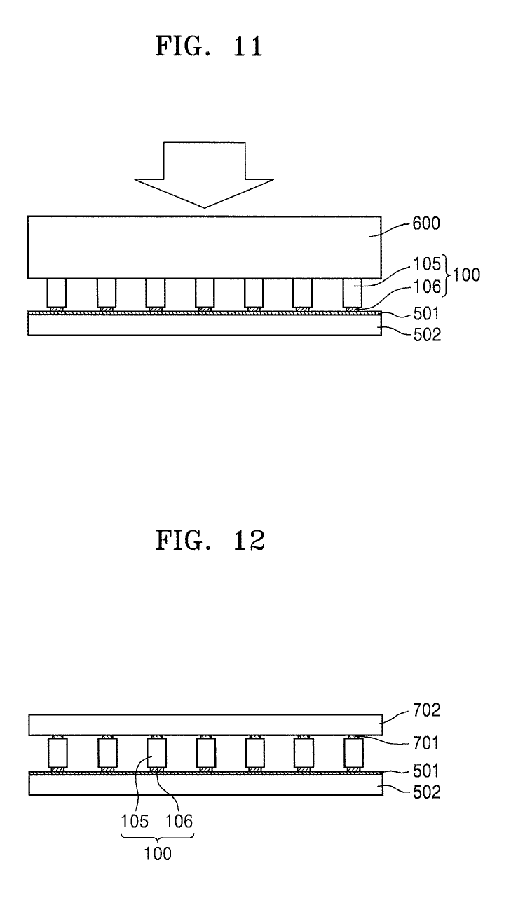

FIG. 11 is a cross-sectional view illustrating an exemplary embodiment of a process in which the LED chip 100 is connected with the first wiring 501.

Referring to FIG. 11, with the first wiring 501 on the first flexible substrate 502 and aligned with the first electrode pad 106 of the LED chip 100, a pressurizing member 600 is located on the LED chip 100 and pressurizes (indicated by the downward arrow) the first electrode pad 106 to bond and connect the first electrode pad 106 to the first wiring 501. Alternatively, the first electrode pad 106 may be bonded to the first wiring 501 by using Joule heat. A single pressuring member 600 may bond multiple LED chips 100 to a first wiring 501 at substantially a same time, but the invention is not limited thereto.

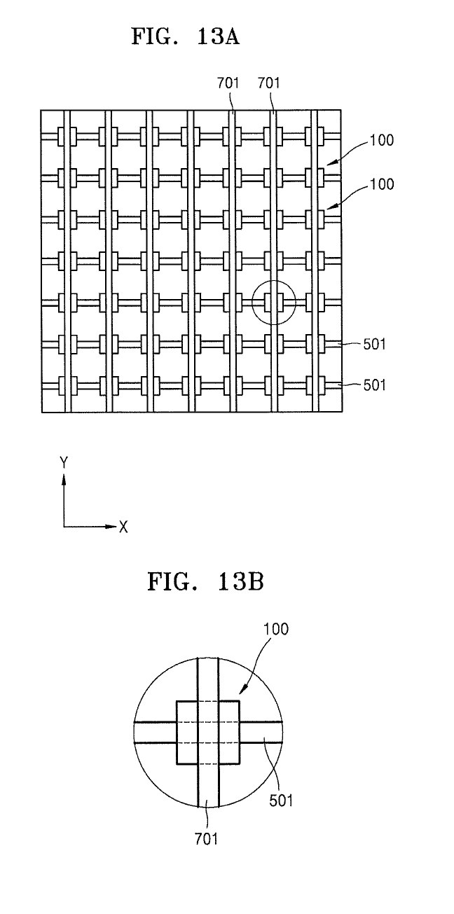

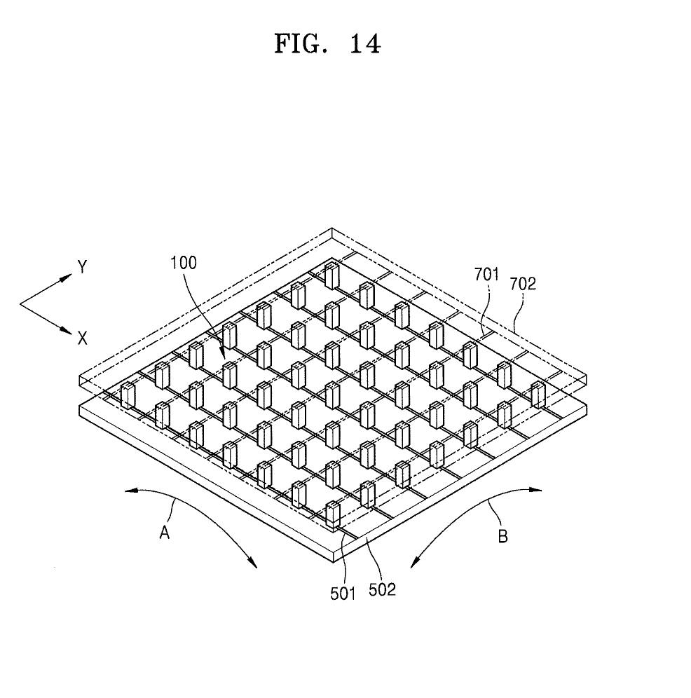

FIG. 12 is a cross-sectional view illustrating an exemplary embodiment of an assembled states of the display device for which a plurality of LED chips is disposed on a first flexible substrate, and a second flexible substrate is aligned on the plurality of LED chips on the first flexible substrate, FIGS. 13A and 13B are top plan views of the display device of FIG. 12, and FIG. 14 is a perspective view of the display device in FIG.

Referring to FIGS. 12 to 14, the plurality of first wirings 501 extended lengthwise parallel to a first direction X is provided on the first flexible substrate 502 and a second wiring 701 provided in plural extended lengthwise parallel to a second direction Y crossing the first direction X is provided on a second flexible substrate 702. A respective plane of the first and second flexible substrates 502 and 702 is defined in the first and second directions X and Y. The first flexible substrate 502 including the first wirings 501 thereon and the second flexible substrate 702 including the second wirings 701 thereof are disposed to face each other with the plurality of LED chips 100 disposed therebetween. FIG. 12 is a view of the first direction X, where a single first wiring 501 is extended in the first direction X while multiple second wirings 701 are disposed in the first direction X.

Like the first flexible substrate 502, the second flexible substrate 702 may include a plastic material. In an exemplary embodiment, for example, the second flexible substrate 702 may include polyether sulphone (“PES”), polyacrylate (“PAR”), polyether imide (“PEI”), polyethylene naphthalate (“PEN”), polyethylene terepthalate (“PET”), polyphenylene sulfide (“PPS”), polyallylate, polyimide, polycarbonate (“PC”), cellulose triacetate (“TAC”) and cellulose acetate propionate (“CAP”).

The second wiring 701 may include a relatively low resistance metallic material. In an exemplary embodiment, for example, the second wiring 701 may include a single layer structure or a multi layer structure including at least one of Al, Pt, Pd, Ag, Mg, Au, Ni, Nd, Ir, Cr, Li, Ca, Mo, Ti, W and Cu.

Similar to the first wiring 501, the second wiring 701 is lengthwise extended to define an extension direction thereof, and a width of the second wiring 701 is defined perpendicular to the extension direction thereof. The width of the second wiring 701 is smaller than that of the LED chip 100.

The second wiring 701 may be electrically connected with an upper surface of the LED chip 100, that is, at the second semiconductor layer 104 (see FIG. 1). Though not shown in the drawings, the LED chip 100 may be electrically connected with the second wiring 701 by using Joule heat or a laser. In an exemplary embodiment of electrically connecting the second wiring 701 with the upper surface of the LED chip 100, although not shown in the drawings, a conductive ball having high conductivity may be further disposed between the LED chip 100 and the second wiring 701.

Referring to FIGS. 13A and 13B, the first and second wirings 501 and 701 connected to an LED chip 100 overlap the LED chip 100

According to one or more exemplary embodiment of the above-described manufacturing method, a display device including the LED chip 100 is driven in a passive matrix (“PM”) method in which a plurality of LED chips 100 share scan lines and data lines, as compared to an active matrix (“AM”) method in which at least one thin film transistor is connected to each LED chip 100. Therefore, power consumption of the display device may be reduced.

Referring to FIG. 14, since the first wiring 501 is extended lengthwise in a direction parallel to the first direction X, the first flexible substrate 502 has flexibility in a first curved direction A taken in the first direction X. Also, since the second wiring 701 is extended lengthwise in a direction parallel to the second direction Y, the second flexible substrate 702 has flexibility in a second curved direction B taken in the second direction Y. Both the first and second curved directions A and B are also defined in a third direction perpendicular to the first and second directions X and Y, such as from a plane of the first and second flexible substrates 502 and 702, respectively. While the first and second curved directions A and B are illustrated in FIG. 14 as deformed in a down direction relative to planes of the first and second flexible substrates 502 and 702, the invention is not limited thereto. In exemplary embodiments, the first and/or second curved directions A and B may be deformed in an up direction relative to planes of the first and second flexible substrates 502 and 702. That is, even though the display device including the LED chips 100 in a PM structure, the display device is deformable in up/down directions and first/second directions X and Y.

Also, since an individual LED chip 100 is connected to a first wiring 501 extended in the first direction X and a second wiring 701 extended in the second direction Y, the first and second wirings 501 and 701 remain doubly connected to the LED chip 100 in up and down directions and in a diagonal line (e.g., X and Y directions and those direction inclined therebetween), a contact failure between the wirings and the chip may reduce and thus reliability of the display device may improve.

Also, since the mask including an opening corresponding to a wiring having the PM structure is used, transferring and aligning of an LED with the wiring may be performed relatively simply.

Though the invention has been described with reference to exemplary embodiments illustrated in the drawings, these are provided for an exemplary purpose only, and those of ordinary skill in the art will understand that various modifications and other equivalent embodiments may be made therein. Therefore, the spirit and scope of the invention should be defined by the following claims.

What is claimed is:

1. A method of manufacturing a display device, the method comprising:
immersing a mask comprising an opening defined therein in plural, in a solution;
seating a light-emitting diode chip provided in plural respectively in the openings of the mask in the solution;
in the solution, arranging a first flexible substrate comprising a first wiring in plural thereon, below the mask, and aligning the first wirings on the first flexible substrate to respectively correspond to the openings of the mask;
removing from the solution, the first flexible substrate with the first wirings corresponding to the openings of the mask together with the mask with the light-emitting diode chips seated in the openings thereof;
bonding the light-emitting diode chips and the first wirings to each other;
providing a second flexible substrate comprising a second wiring in plural thereon, and aligning the second wirings on the second flexible substrate to respectively correspond to the light-emitting diode chips; and
bonding the light-emitting diode chips and the second wirings to each other, to form the display device.

2. The method of claim 1, wherein the seating the light-emitting diode chip comprises:
seating a single one light-emitting diode chip in each of the openings of the mask.

3. The method of claim 1, wherein the second wirings lengthwise extend in a direction crossing a direction in which the first wirings lengthwise extend.

4. The method of claim 1, wherein the openings respectively correspond to locations where the first wirings cross the second wirings.

5. The method of claim 1, further comprising:
removing the mask from the light-emitting diode chips seated in the openings thereof, before the bonding the light-emitting diode chips and the first wirings to each other.

6. The method of claim 1, further comprising for each light-emitting diode chip seated in the mask:
disposing a first electrode pad on a first end of the light-emitting diode chip before the seating the light-emitting diode chip.

7. The method of claim 6, wherein the first electrode pad comprises a material having a density greater than that of the light-emitting diode chip.

8. The method of claim 6, wherein the bonding the light-emitting diode chips and the first wirings to each other comprises bonding the first electrode pad to the first wiring by using pressurization and/or Joule heat.

9. The method of claim 1, wherein the solution comprises fluorine.

10. The method of claim 1, wherein
the mask comprises a magnetic material, and
the light-emitting diode chip is coated with the magnetic material.

11. The method of claim 1, wherein
the light-emitting diode chips each comprise a semiconductor compound, further comprising:
disposing the light-emitting diode chips comprising the semiconductor compound on a base substrate,
processing the light-emitting diode chips disposed on the base substrate to be separable from the base substrate,
transferring the separable light-emitting diode chips to a carrier substrate, and
removing the base substrate from the separable light-emitting diode chips to dispose the light-emitting diode chips on the carrier substrate.

12. The method of claim 1, wherein a minimum size of the opening of the mask is greater than a maximum size of the light-emitting diode chip.

13. The method of claim 1, wherein the seating the light-emitting diode chip in the opening of the mask in the solution comprises moving the light-emitting diode chip up and down within the solution by using a laser.

14. The method of claim 1, wherein the seating the light-emitting diode chip in the opening of the mask in the solution comprises moving the light-emitting diode chip up and down within the solution by using an ultrasonic wave.

15. The method of claim 1, wherein both a width of the first wiring taken perpendicular to a length thereof and a width of the second wiring taken perpendicular to a length thereof, are less than a width of the light-emitting diode chip taken perpendicular to a length thereof.

16. A display device manufactured by the method of claim 1.
